(19) United States
(12) Patent Application Publication
(10) Pub. No.: US 2026/0324243 A1
(43) Pub. Date: Oct. 15, 2026

(54) Display Panel, And Electronic Apparatus Including The Same

(71) Applicant: Samsung Display Co., Ltd., Yongin-si (KR)

(72) Inventor: Hyungguen Yoon, Yongin-si (KR)

(73) Assignee: Samsung Display Co., Ltd., Yongin-si (KR)

(21) Appl. No.: 19/466,634

(22) Filed: Feb. 2, 2026

(30) Foreign Application Priority Data
Mar. 13, 2025 (KR) 10+2025-0032711

(51) Int. Cl. H10K 59/38

(52) U.S. Cl. CPC H10K 59/38

(57) ABSTRACT

Provided is a display panel. The display panel comprises a base layer defining a plurality of light-emitting areas comprising a first light-emitting area emitting a light of a first wavelength and a second light-emitting area adjacent to the first light-emitting area and emitting a light of a second wavelength different from the first wavelength, and a non-light-emitting area surrounding the plurality of light-emitting areas, a first layer disposed on the base layer and comprising a light control pattern overlapping the second light-emitting area, a second layer disposed on the first layer and comprising a light-emitting element emitting the light of the first wavelength, and a third layer disposed on the second layer and comprising an optical pattern overlapping the second light-emitting area. The optical pattern comprises a photonic crystal.

### CROSS-REFERENCE TO RELATED APPLICATIONS

This application claims priority under 35 U.S.C. § 119 to Korean Patent Application No. 10-2025-0032711, filed on Mar. 13, 2025, the entire contents of which are hereby incorporated by reference.

### BACKGROUND

The present disclosure herein relates to a display panel and an electronic device including the same, and more particularly, to a display panel including quantum dots and an electronic device includes the same.

Various display devices for providing image information in a multi-media device such as a television, a mobile phone, a tablet computer, a navigation system, a game machine, and the like have been developed.

In particular, in a display device or the like including a liquid crystal display element, an organic light-emitting display element, or the like, quantum dots or the like are introduced in order to improve display quality. In display devices including quantum dots, a method for increasing light emission efficiency has been studied.

### SUMMARY

The present disclosure provides a display panel with improved light emission efficiency, and an electronic device including the same.

An aspect of the present disclosure provides a display panel comprising a base layer defining a plurality of light-emitting areas comprising a first light-emitting area emitting a light of a first wavelength and a second light-emitting area adjacent to the first light-emitting area and emitting a light of a second wavelength different from the first wavelength, and a non-light-emitting area surrounding the plurality of light-emitting areas, a first layer disposed on the base layer and comprising a light control pattern overlapping the second light-emitting area, a second layer disposed on the first layer and comprising a light-emitting element emitting the light of the first wavelength, and a third layer disposed on the second layer and comprising an optical pattern overlapping the second light-emitting area. The optical pattern comprises a photonic crystal.

In an aspect, the third layer may comprise a first color filter that overlaps the first light-emitting area and the non-light-emitting area and transmits the light of the first wavelength.

In an aspect, the display panel may further comprise a fourth layer disposed on the third layer. The fourth layer may comprise a second color filter that overlaps the second light-emitting area and transmits the light of the second wavelength.

In an aspect, the display panel may further comprise a fourth layer disposed on the third layer. The fourth layer may comprise a polarizer overlapping the first light-emitting area, the second light-emitting area and the non-light-emitting area.

In an aspect, the light of the first wavelength may be blue light.

In an aspect, the first light control pattern may comprise a first quantum dot. The first quantum dot may convert the light of the first wavelength into the light of the second wavelength.

In an aspect, a thickness of the optical pattern may be 1μm or more and 10μm or less.

In an aspect, the optical pattern may have a reflectance of 45% or more with respect to the light of the first wavelength.

In an aspect, the optical pattern may have a transmittance of 90% or more with respect to the light of the second wavelength.

In an aspect, the photonic crystal may comprise a helical photonic crystal.

In an aspect, the optical pattern may comprise a first optical pattern comprising a first photonic crystal, and a second optical pattern disposed on the first optical pattern and comprising a second photonic crystal having a helical rotation direction different from that of the first photonic crystal.

In an aspect, the optical pattern may have a reflectance of 90% or more with respect to the light of the first wavelength.

In an aspect, the helical photonic crystal may comprise a plurality of threads. The number of the plurality of threads may be four or more.

In an aspect, a distance between adjacent ones of the plurality of threads may be greater than or equal to 200nm and less than or equal to 350nm.

In an aspect, a refractive index anisotropy of the optical pattern with respect to the light of the first wavelength may be 0.1 or more and 0.3 or less.

In an aspect, the first layer may further comprise a first partition wall in which a first opening overlapping the second light-emitting area is defined, and a reflective member disposed in the first opening.

In an aspect, the light control pattern may be disposed on the reflective member.

In an aspect, the light-emitting element may comprise a first light-emitting pattern overlapping the first light-emitting area and a second light-emitting pattern overlapping the second light-emitting area. The light control pattern may be disposed below the second light-emitting pattern. The optical pattern may be disposed on the second light-emitting pattern.

In an aspect, the display panel may further comprise a circuit element layer disposed between the base layer and the first layer.

An aspect of the present disclosure provides an electronic apparatus providing an image, the electronic apparatus comprising a display device, and a power module supplying power to the display device. The display device comprises a display panel and a window disposed on the display panel. The display panel comprises a base layer defining a plurality of light-emitting areas comprising a first light-emitting area emitting a light of a first wavelength and a second light-emitting area adjacent to the first light-emitting area and emitting a light of a second wavelength different from the first wavelength, and a non-light-emitting area surrounding the plurality of light-emitting areas, a first layer disposed on the base layer and comprising a light control pattern overlapping the second light-emitting area, a second layer disposed on the first layer and comprising a light-emitting element emitting the light of the first wavelength, and a third layer disposed on the second layer and comprising an optical pattern overlapping the second light-emitting area. The optical pattern comprises a photonic crystal.

### BRIEF DESCRIPTION OF THE FIGURES

FIG. 1 is a block diagram of an electronic device according to an aspect.

FIG. 2 is a schematic diagram of an electronic device according to various aspects.

FIG. 3 is a perspective view of a display device according to an aspect of the present disclosure.

FIG. 4 is a cross-sectional view of a display device according to an aspect of the present disclosure.

FIG. 5 is a plan view of a display panel according to an aspect of the present disclosure.

FIG. 6 is a circuit diagram of a pixel according to an aspect of the present disclosure.

FIG. 7 is a plan view of pixels according to an aspect of the present disclosure.

FIG. 8 is a cross-sectional view of a display panel according to an aspect of the present disclosure.

FIG. 9 is a cross-sectional view schematically illustrating a light-emitting element according to an aspect of the present disclosure.

FIG. 10 is an enlarged cross-sectional view of a portion of a display panel according to an aspect of the present disclosure.

FIGS. 11A and 11B are enlarged cross-sectional views of a portion of a display panel according to an aspect of the present disclosure.

FIG. 12 is a cross-sectional view of a display panel according to another aspect of the present disclosure.

FIGS. 13A and 13B are cross-sectional views of a display panel according to another aspect of the present disclosure.

### DETAILED DESCRIPTION

The present disclosure is capable of various modifications and various forms, and specific aspects are illustrated in the drawings and described in detail in the specification. It is to be understood, however, that this is not intended to limit the present disclosure to any particular form of disclosure, but is to cover all modifications, equivalents, or substitutions falling within the spirit and scope of the present disclosure.

In this specification, it will be understood that when an element (or a region, a layer, a portion, or the like) is referred to as being "on", "connected to" or "coupled to" another element, it can be directly disposed on, connected to, or coupled to the other element or layer or other elements may be disposed therebetween.

Like reference numerals or symbols refer to like elements throughout. In the drawings, the thickness, ratio, and size of the elements are exaggerated for effectively describing the technical contents. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the present disclosure. Similarly, a second element could be termed a first element. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skills in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel and an electronic device including the same according to aspects of the present disclosure are described with reference to the drawings.

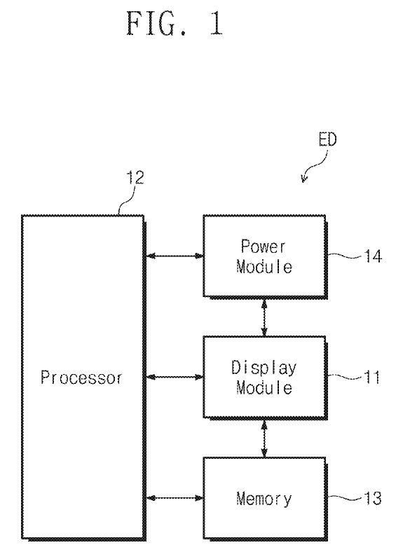

FIG. 1 is a block diagram of an electronic device according to an aspect.

Referring to FIG. 1, an electronic device ED according to an aspect may include a display module 11, a processor 12, a memory 13, and a power module 14. The electronic device ED according to an aspect of the present disclosure includes a display device DD (see FIG. 3) to be described later, and may further include a module or device having an additional function other than the display device DD (FIG. 3). The display device DD (see FIG. 3) according to an aspect of the present disclosure may be applied to various electronic devices ED.

The processor 12 may include at least one of a central processing unit (CPU), an application processor (AP), a graphics processing unit (GPU), a communication processor (CP), an image signal processor (ISP), or a controller.

The memory 13 may store data information necessary for operation of the processor 12 or the display module 11. When the processor 12 executes the application stored in the memory 13, an image data signal and/or an input control signal are transmitted to the display module 11, and the display module 11 may process the received signal to an output image information through a display screen.

The power module 14 may include a power supply module such as a power adapter or a battery device, and a power conversion module that converts power supplied by the power supply module to generate power required for operation of the electronic device ED.

At least one of the above-described components of the electronic device ED may be included in the display device according to the above-described aspects. In addition, some of the individual modules that are functionally included in one module may be included in the display device, and other parts may be provided separately from the display device. For example, the display device includes the display module 11, and the processor 12, the memory 13, and the power module 14 may be provided in the form of other devices in the electronic device ED other than the display device.

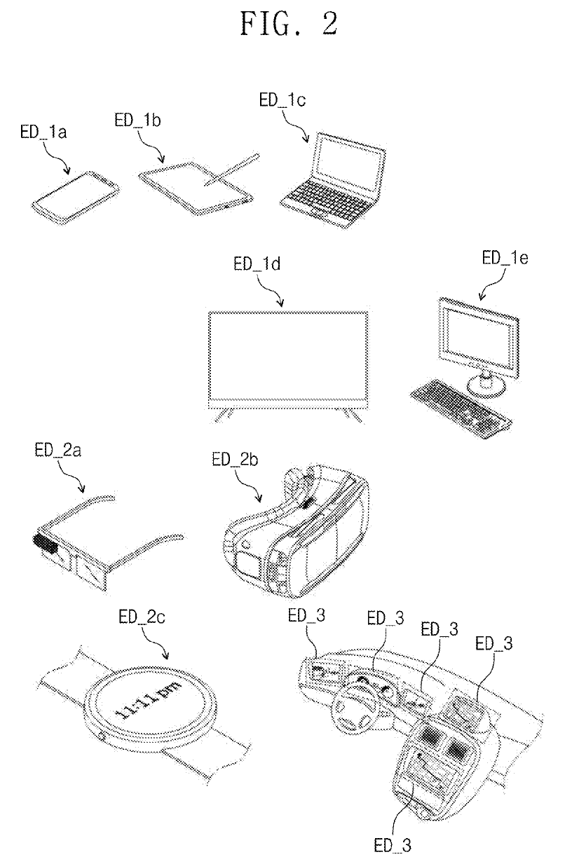

FIG. 2 is a schematic diagram of an electronic device according to various aspects.

Referring to FIG. 2, various electronic devices to which a display device according to aspects is applied may include not only an electronic device for image display such as a smartphone ED_1a, a tablet PC ED_1b, a laptop ED_1c, a TV ED_1d, and a desk monitor ED_1e, but also a wearable electronic device including a display module such as smart glasses ED_2a, a head mounted display ED_2b, a smart watch ED_2c, and the like, an electronic device for a vehicle ED_3 including a display module, such as a CID (Center Information Display) disposed on an instrument panel, a center fascia, or a dashboard of a vehicle, a room mirror display, and the like. In addition, these are only those presented as examples, and may also be employed as other electronic devices without departing from the concept of the present disclosure.

FIG. 3 is a perspective view of a display device according to an aspect of the present disclosure.

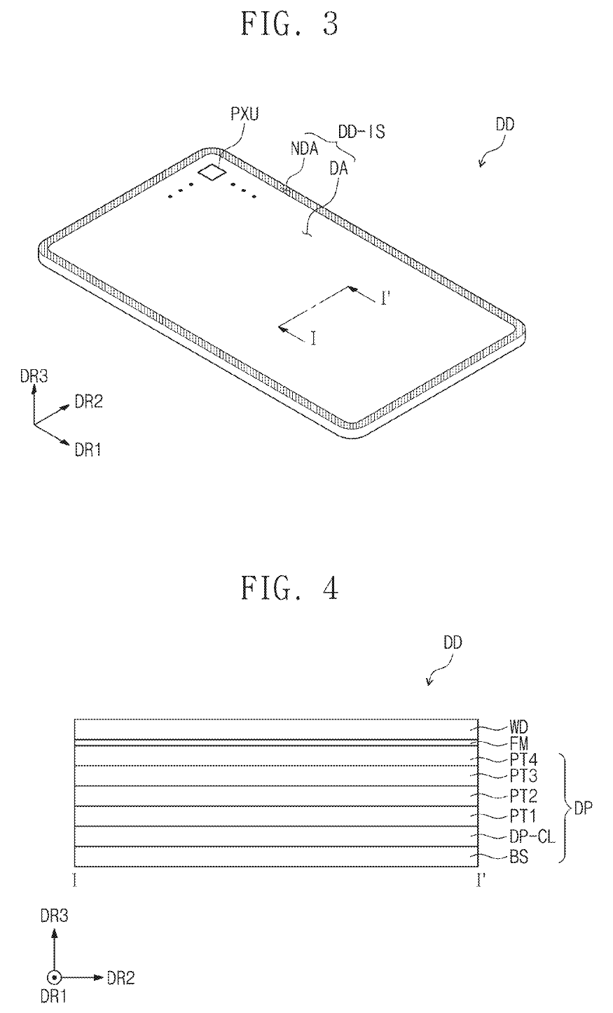

Referring to FIG. 3, a display device DD may display an image through a display surface DD-IS. An upper surface of a member disposed on the uppermost side of the display device DD may be defined as the display surface DD-IS. According to the present disclosure, an upper surface of a window WD illustrated in FIG. 4 may be provided as the display surface DD-IS of the display device DD.

The display surface DD-IS may be parallel to a surface defined by a first direction DR1 and a second direction DR2. A normal direction of the display surface DD-IS, that is, a thickness direction of the display device DD indicates a third direction DR3. A front surface (or a top surface) and a back surface (or a bottom surface) of each of layers or units described below are divided by the third direction DR3.

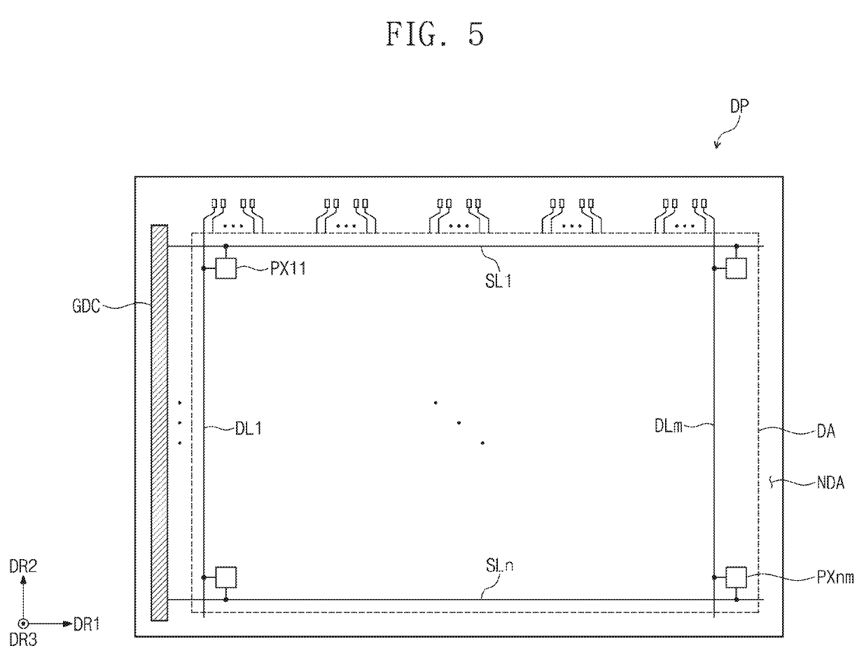

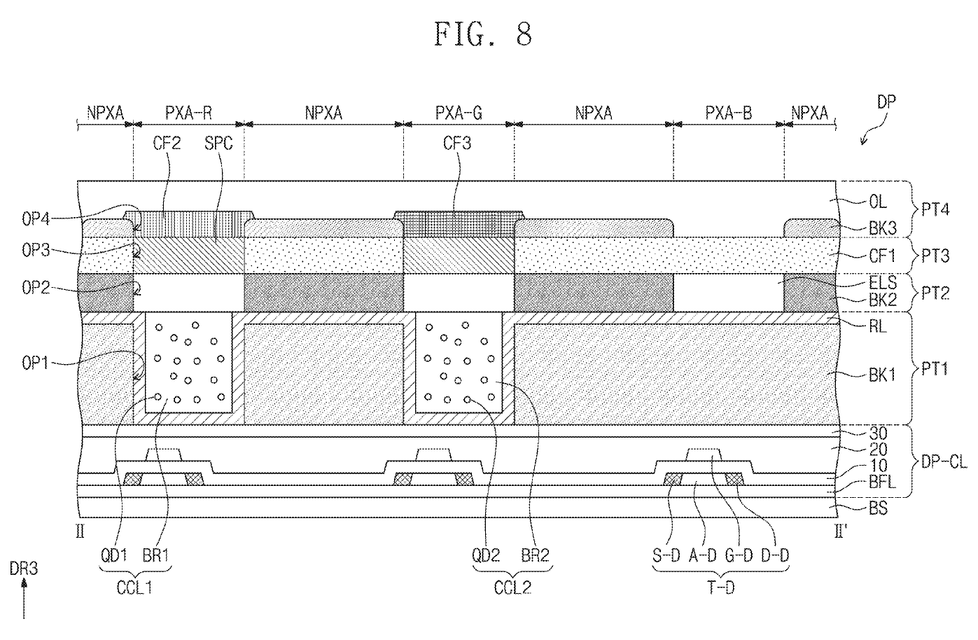

The display device DD may include a display area DA and a non-display area NDA. A light-emitting element ELS (see FIG. 8) included in a pixel PXnm (see FIG. 5) is disposed in the display area DA, and a light-emitting element ELS (see FIG. 8) of a pixel PXnm (see FIG. 5) is not disposed in the non-display area NDA. The non-display area NDA is defined along the edge of the display surface DD-IS. The non-display area NDA may surround the display area DA. In an aspect of the present disclosure, the non-display area NDA may be omitted or disposed only on one side of the display area DA.

FIG. 3 illustrates a unit pixel PXU disposed in the display area DA. The unit pixel PXU may include at least two pixels that provide different light. For example, the unit pixel PXU may be a region in which pixels that provide source light are disposed. The emission area, shape, and arrangement form of each of the pixels included in the unit pixel PXU are not limited to any particular one. For example, emission areas of each of the pixels included in the unit pixel PXU may be different from each other. It can also have a circular or polygonal shape on each of the light-emitting areas plane.

FIG. 4 is a cross-sectional view of a display device according to an aspect of the present disclosure. FIG. 4 shows a cross section cut along a I-I′ cut line shown in FIG. 3.

Referring to FIG. 4, the display device DD according to an aspect of the present disclosure may include a display panel DP, a window WD, and a filler FM disposed between the display panel DP and the window WD. The display panel DP may include a base layer BS, a circuit element layer DP-CL, and first to fourth layers PT1, PT2, PT3, and PT4.

The base layer BS may include a synthetic resin layer. The synthetic resin layer may include a thermosetting resin. In particular, the synthetic resin layer may include at least one of an acrylic resin, a methacrylic resin, a polyisoprene, a vinyl resin, an epoxy resin, a urethane resin, a cellulose resin, a siloxane resin, a polyamide resin, or a perylene resin. In addition, the base layer BS may include a glass substrate, a metal substrate, an organic/inorganic composite material substrate, or the like.

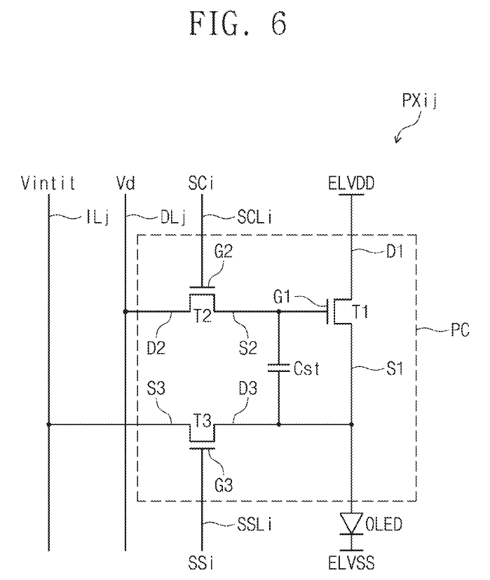

The circuit element layer DP-CL forms an insulating layer, a semiconductor layer, and a conductive layer through a process such as coating and vapor deposition. Then, the insulating layer, the semiconductor layer, and the conductive layer can be selectively patterned through a photolithography and etching process. Through this process, a semiconductor pattern, a conductive pattern, a signal line, and the like can be formed. Patterns disposed at the same layer may be formed through the same process. The circuit element layer DP-CL may include a driving circuit or a signal line constituting a pixel PXij (see FIG. 6).

The first to fourth layers PT1 to PT4 may be sequentially stacked. The first layer PT1 may correspond to a layer that includes quantum dots to change the color of a source light, the second layer PT2 may correspond to a layer that provides the source light, and the third layer PT3 may correspond to a layers that reflect or transmit light provided in the first layer PT1 and the second layer PT2, or light provided on the display surface DD-IS (see FIG. 3) according to a light wavelength. The fourth layer PT4 may be a layer including a color filter that filters an emitted light to improve color purity of the light. The first to fourth layers PT1 to PT4 will be described later in detail with reference to FIGS. 8 - 12B.

The window WD may be disposed on the fourth layer PT4. The window WD may transmit light provided from the display panel DP to an outside. The window WD may distinguish the display area DA and the non-display area NDA of the display surface DD-IS as illustrated in FIG. 3. A boundary between the display area DA and the non-display area NDA may be defined by a bezel pattern disposed under the window WD and absorbing light. Although not shown, the window WD may include a base layer and functional layers disposed on the base layer. The base layer of the window WD may be made of glass, sapphire, plastic, or the like. The functional layers of the window WD may include a protective layer, an anti-fingerprint layer, and the like.

FIG. 5 is a plan view of a display panel according to an aspect of the present disclosure.

FIG. 5 illustrates a planar arrangement between signal lines SL1 to SLn and DL1 to DLm and pixels PX11 to PXnm included in the display panel DP. The display panel DP according to an aspect may include a plurality of scan lines SL1 to SLn and a plurality of data lines DL1 to DLm of signal lines SL1-SLn and DL1-DLm.

The pixels PX11 to PXnm may be disposed in the display area DA. Each of the pixels PX11 to PXnm is connected to a corresponding one of the plurality of scan lines SL1 to SLn and a corresponding one of a plurality of data lines DL1 to DLm. Each of the pixels PX11 to PXnm may include a pixel driving circuit and a light-emitting element. More types of signal lines may be provided in the display device DP according to a configuration of the pixel driving circuits of the pixels PX11 to PXnm.

A gate driving circuit GDC may be disposed in the non-display area NDA. The gate driver circuit GDC may be integrated into the display device DP through an oxide silicon gate driver circuit (OSG) or an amorphous silicon gate driver circuit (ASG) process.

FIG. 6 is a circuit diagram of a pixel according to an aspect of the present disclosure.

FIG. 6 illustrates a circuit diagram of one-pixel PXij among the pixels PX11 to PXnm (see FIG. 5), as an example. The pixel PXij may include a pixel circuit PC and a light-emitting element OLED. The pixel circuit PC may include a plurality of transistors T1 to T3 and a capacitor Cst.

The plurality of transistors T1 to T3 may be formed through an LTPS (Low Temperature Polycrystalline Silicon) process or an LTPO (Low Temperature polycrystalline Oxide) process. Each of the first to third transistors T1 to T3 may include any one of a silicon semiconductor and an oxide semiconductor. In this case, the oxide semiconductor may include a crystalline or amorphous oxide semiconductor, and the silicon semiconductor may include an amorphous silicon, a polycrystalline silicon, or the like, which is not limited to any one aspect.

Hereinafter, the first to third transistors T1 to T3 are described as N-type transistors, but are not limited thereto, and each of the first to third semiconductor transistors T1 and T3 may be a P-type transistor or an N-type transistor according to an applied signal. In this case, a source and a drain of the P-type transistor may correspond to a drain and a source of the N-type transistor, respectively.

FIG. 6 illustrates the pixel PXij connected to an i-th scan line SCLi, an i-th sensing line SSLi, a j-th data line DLj, and a j-th initial line ILj, as an example.

The pixel circuit PC may include the first transistor T1(a driving transistor), the second transistor T2(a switch transistor), the third transistor T3(a sensing transistor), and the capacitor Cst. However, the pixel circuit PC may further include an additional transistor and an additional capacitor and is not limited to any one aspect.

The light-emitting element OLED may be an organic light-emitting element or an inorganic light-emitting element including a first electrode (anode) and a second electrode (cathode). The first electrode of the light-emitting element OLED may receive the first voltage ELVDD through the first transistor T1, and the second electrode of the light-emitting element OLED may receive a second voltage ELVSS. The light-emitting element OLED may receive the first voltage ELVDD and the second voltage ELVSS to emit light.

The first transistor T1 may include a drain D1 that receives the first voltage ELVDD, a source S1 connected to an anode of the light-emitting element OLED, and a gate G1 connected to the capacitor Cst. The first transistor T1 may control a driving current flowing through the light-emitting element OLED from the first voltage ELVDD in response to a voltage value stored in the capacitor Cst.

The second transistor T2 may include a drain D2 connected to the j-th data line DLj, a source S2 connected to the capacitor Cst, and a gate G2 that receives a i-th first scan signal SCi. The second transistor T2 provides a data voltage Vd to the first transistor T1 in response to the i-th first scan signal SCi.

The third transistor T3 may include a source S3 connected to the j-th initial line ILj, a drain D3 connected to the anode of the light-emitting element OLED, and a gate G3 that receives the i-th second scan signal SSi. The j-th initial line ILj may receive an initial voltage Vintit.

The capacitor Cst may store voltage differences of various values according to an input signal. For example, the capacitor Cst may store a voltage corresponding to a difference between a voltage received from the second transistor T2 and the first voltage ELVDD.

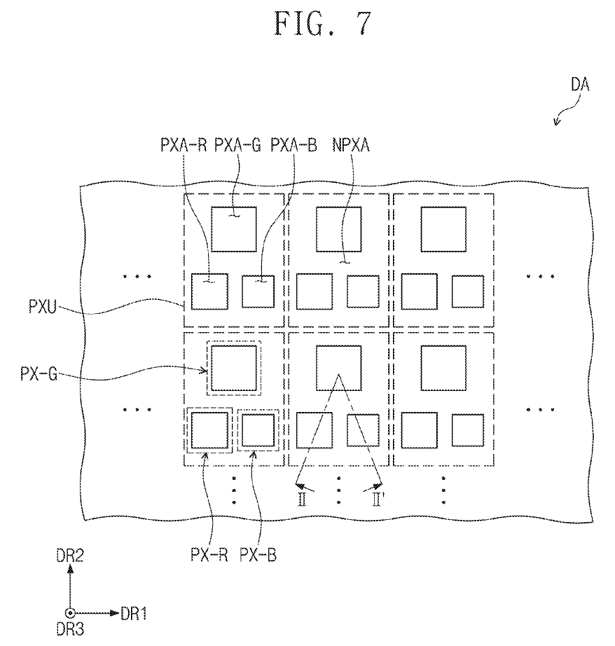

FIG. 7 is a plan view of pixels according to an aspect of the present disclosure.

Referring to FIG. 7, the display area DA may include a plurality of light-emitting areas PXA-B, PXA-R, and PXA-G and a non-light-emitting area NPXA surrounding the light-emitting areas PXA-B, PXA-R, and PXA-G. The non-light-emitting area NPXA may be defined between the first light-emitting area PXA-B, the second light-emitting area PXA-R, and the third light-emitting area PXA-G. The non-light-emitting area NPXA may set a boundary between the first to third light-emitting areas PXA-B, PXA-R, and PXA-G, and may prevent color mixing between the first to the third light-emitting areas PXA-B, PXA-R, and PXA-G.

Each of the first to third pixels PX-B, PX-R, and PX-G may include a light-emitting element ELS (see FIG. 8). Light generated in the light-emitting elements ELS (see FIG. 8) of the first to third pixels PX-B, PX-R, and PX-G may be emitted through the first light-emitting area PXA-B, the second light-emitting area PXA-R, and the third light-emitting area PXA-G. Light formed in the first pixel PX-B may be provided to the first light-emitting area PXA-B, light formed in the second pixel PX-R may be provided to the second light-emitting area PXA-R, and light formed in the third pixel PX-G may be provided to third light-emitting area PXA-G. The first to third light-emitting areas PXA-B, PXA-R, and PXA-G may correspond to fourth openings OP4 to be described later in FIG. 8.

Each of the first light-emitting area PXA-B, the second light-emitting area PXA-R, and the third light-emitting area PXA-G may provide lights having different wavelengths. The first light-emitting area PXA-B may provide light of a first wavelength that is blue light, the second light-emitting area PXA-R may provide light of a second wavelength that is red light, and the third light-emitting area PXA-G may provide light of a third wavelength that is green light. An aspect is not limited thereto, and the first light-emitting area PXA-B, the second light-emitting area PXA-R, and the third light-emitting area PXA-G may emit light of a color other than the blue wavelength light, the red wavelength light, and the green wavelength light described above.

The first light-emitting area PXA-B and the second light-emitting area PXA-R may be disposed in the same row, and the third light-emitting area PXA-G may be disposed in a different row from the first light-emitting area PXA-B and second light-emitting area PXA-R. For example, the first light-emitting area PXA-B and the second light-emitting area PXA-R may be spaced apart from each other along the first direction DR1, and the third light-emitting area PXA-G may be spaced away from the first light-emitting area PXA-B and second light-emitting area PXA-R in oblique direction of the first direction DR1 and the second direction DR2, respectively. An arrangement structure of the first light-emitting area PXA-B, the second light-emitting area PXA-R, and the third light-emitting area PXA-G in the unit pixel PXU illustrated in FIG. 7 is an example, and is not limited thereto. For example, the first light-emitting area PXA-B, the second light-emitting area PXA-R, and the third light-emitting area PXA-G may be arranged along the first direction DR1 and disposed in the same row. In addition, the arrangement of the first light-emitting area PXA-B, the second light-emitting area PXA-R, and the third light-emitting area PXA-G of each of the unit pixels PXU may not necessarily be the same. The first light-emitting area PXA-B, the second light-emitting area PXA-R, and the third light-emitting area PXA-G may have a stripe structure in which the first light-emitting area PXA-B, the second light-emitting area PXA-R, and the third light-emitting area PXA-G are sequentially and alternately arranged, and the arrangement structure of the first, second, and third light-emitting areas PXA-B, PXA-R and PXA-G may have a structure in the form of a pentile (PENTILE^{TM}) or diamond arrangement.

An area of the second light-emitting area PXA-R may be smaller than an area of the third light-emitting area PXA-G and larger than an area of the first light-emitting area PXA-B. In addition, each of the first light-emitting area PXA-B, the second light-emitting area PXA-R, and the third light-emitting area PXA-G may have a square shape. However, an area ratio and a shape of the light-emitting areas are not limited to those shown. For example, the first light-emitting area PXA-B, the second light-emitting area PXA-R, and the third light-emitting area PXA-G may have various polygonal shapes or circular shapes, and the first light-emitting area PXA-B, the second light-emitting area PXA-R, or the third light-emitting area PXA-G may be provided at different area ratios of the pixel areas.

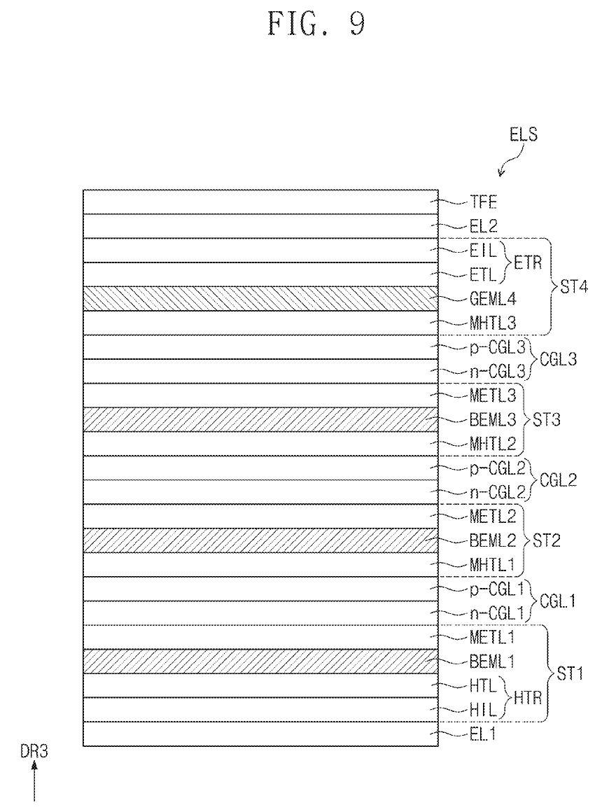

FIG. 8 is a cross-sectional view of a display panel according to an aspect of the present disclosure. FIG. 9 is a cross-sectional view schematically illustrating a light-emitting element according to an aspect of the present disclosure. FIG. 8 shows a cross section cut along a II-II′ cut line shown in FIG. 7. Hereinafter, a stacked-layer structure of the display panel DP will be described with reference to FIGS. 8 and 9.

Referring to FIG. 8, the display panel DP may include the base layer BS, the circuit element layer DP-CL, the first layer PT1, the second layer PT2, the third layer PT3, and the fourth layer PT4.

The base layer BS may provide a base surface on which a buffer layer BFL included in the circuit element layer DP-CL, first to third insulating layers 10 to 30, and transistors T-D may be disposed. Although a single-layer base layer is illustrated in FIG. 8, the base layer BS may be provided as a multilayer in which an organic layer and an inorganic layer are sequentially stacked, and is not limited to any one aspect.

The circuit element layer DP-CL may be disposed on the base layer BS. The circuit element layer DP-CL may include the buffer layer BFL, the first insulating layer 10, the second insulating layer 20, the third insulating layer 30, and the transistor T-D. The transistor T-D may be any one of the first to third transistors T1 to T3 described with reference to FIG. 6. However, the configuration included in the circuit element layer DP-CL is not limited to the illustrated configuration. For example, the circuit element layer DP-CL may further include light shielding patterns (not shown) disposed on the base layer BS.

The first insulating layer 10 may be disposed on the buffer layer BFL. The first insulating layer 10 may overlap a plurality of pixels in common and covers a semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon oxynitride, zirconium oxide, or hafnium oxide. An insulating layer of the circuit element layer DP-CL described later as well as the first insulating layer 10 may be an inorganic layer and/or an organic layer and may have a single-layer or multi-layer structure.

The transistor T-D may include an active A-D, a source S-D, a drain D-D, and a gate G-D. The active A-D, the source S-D, and the drain D-D may be disposed on the first insulating layer 10. The active A-D, the source S-D, and the drain D-D may be regions classified according to a doping concentration or conductivity of the semiconductor pattern. The transistor T-D may be directly or indirectly connected to a first electrode EL1 (see FIG. 9) to be described later. Although not shown, the transistor T-D may be connected to the first electrode EL1 (see FIG. 9) through a contact hole defined in a first partition wall BK1 to be described later.

The second insulating layer 20 may be disposed on the first insulating layer 10 to cover the active A-D, the source S-D, and the drain D-D. The first insulating layer 10 may be disposed between the active A-D, the source S-D, and the drain D-D and the gate G-D to be described later.

The gate G-D may be disposed on the first insulating layer 10. According to an aspect, the gate G-D may include sequentially stacked metal layers. The gate G-D may include a first layer including titanium and a second layer including copper.

The third insulating layer 30 is disposed over the second insulating layer 20 and may cover the gate G-D.

The first layer PT1 may be disposed on the circuit element layer DP-CL. The first layer PT1 may be directly disposed on the circuit element layer DP-CL. The first layer PT1 may include the first partition wall BK1, a reflective member RL, a first light control pattern CCL1, and a second light control pattern CCL2.

The first partition wall BK1 may be disposed on the circuit element layer DP-CL. The first partition wall BK1 may include a polymer resin. For example, the first partition wall BK1 may include a polyacrylate-based resin or a polyimide-based resin. The first partition wall BK1 may further include an inorganic material in addition to the polymer resin. The first partition wall BK1 may be formed of an inorganic material. For example, the first partition wall BK1 may include silicon nitride (SiNₓ), silicon oxide (SiOₓ), silicon oxide nitrate (SiOₓN_{y}), or the like.

First openings OP1 may be defined in the first partition wall BK1. The first opening OP1 may expose at least a portion of an upper surface of the circuit element layer DP-CL. The first openings OP1 may overlap the second light-emitting area PXA-R and the third light-emitting area PXA-G, respectively. The first opening OP1 may not be defined in the first light-emitting area PXA-B.

The reflective member RL may overlap the second light-emitting area PXA-R and the third light-emitting area PXA-G and may be disposed in the first opening OP1. The reflective member RL may be disposed along a side surface of the first partition wall BK1 defining the first opening OP1. The reflective member RL may overlap the first light-emitting area PXA-B and the non-light-emitting area NPXA and may be disposed on the first partition wall BK1. The reflective member RL may be disposed to completely overlap the light-emitting areas PXA-B, PXA-R, and PXA-G and the non-light-emitting area NPXA. The reflective member RL may be provided as a continuous single body. Unlike shown in FIG. 8, in another aspect, the reflective member RL is not disposed in the first opening OP1 but may be disposed under the first partition wall BK1.

The reflective member RL may perform a function of reflecting light. In an aspect, the reflective member RL may have a reflectance of at least 90% for visible light. The reflective member RL may comprise a metallic material. The reflective member RL may include aluminum (Al), silver (Ag), magnesium (Mg), an alloy of silver (Ag), magnesium (Mg), and silver (Ag), or the like. However, the type of a metal material included in the reflective member RL is not particularly limited as long as it has a property of reflecting light.

The light control patterns CCL1 and CCL2 may be disposed on the reflective member RL (not shown in FIG. 8). The light control patterns CCL1 and CCL2 may be disposed in the first opening OP1. The light control patterns CCL1 and CCL2 may convert a wavelength of a received light and emit a converted light. The light control patterns CCL1 and CCL2 may include a light converter, for example, a quantum dot.

In this specification, a quantum dot means a crystal of a semiconductor compound. The quantum dots may emit light of various emission wavelengths depending on a size of the crystal. The quantum dots may emit light of various emission wavelengths as an element ratio in the quantum dot compound is adjusted.

The diameter of the quantum dots may be, for example, about 1nm to 10nm. The quantum dots may be synthesized by a wet chemical process, an organometallic chemical vapor deposition process, a molecular beam epitaxy process, or a similar process, or the like.

The wet chemical process in the quantum dot manufacturing process is a method of growing quantum dot particle crystals after mixing an organic solvent and a precursor material. When the quantum dot particle crystal grows, the organic solvent naturally acts as a dispersant coordinated to the quantum dot crystal surface, and can control the growth of the particle crystal. Therefore, the wet chemical process is easier than a vapor deposition method such as metal organic chemical vapor deposition (MOCVD) or molecular beam epitaxy (MBE), and the growth of quantum dot particles can be controlled through a low-cost process.

A core of the quantum dot may be selected from a Group II-VI compound, a Group III-V compound, a Group III-VI compound, a Group I-III-VI compounds, a Group IV-VI compounds, a Group IV elements, a Group IV compounds, and combinations thereof.

The Group II-VI compound is a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and an elemental compound selected from the group consisting of HgZnTeS, CdZnSeS, Cd ZnSeTe, CdZnSTe, CdHgSeS, CdHgSeTe, CdHgSTe, HgZnSeS and HgZnSeTe and mixtures thereof. The Group II-VI semiconductor compound may further include a Group I metal and/or a Group IV element. A Group I-II-VI compound may be selected from CuSnS or CuZnS, and a Group II-IV-VI compound may also be selected from ZnSnS and the like. A Group I-II-IV-VI compounds may be selected from quaternary compounds selected from the group consisting of Cu₂ZnSnS₂, Cu₂ZnSnS₄, Cu₂ZnSnSe₄, Ag₂ZnSnS₂ and mixtures thereof.

The group III-VI compound may comprise a binary compound such as In₂S₃, In₂Se₃, etc., a ternary compound such as InGaS₃, InGaSe₃, etc. or any combination thereof.

The Group I-III-VI compound may be selected from ternary compounds selected from the group consisting of AgInS, AgInS₂, CuInS, CuInS₂, AgGaS₂, CuGaS₂, CuGaO₂, AgGaO₂, and a mixture thereof, or quaternary compounds such as AgInGaS₂, and CuInGaS₂.

The group III-V compound may be selected from the group consisting of a binary compound selected from the group comprising GaN, GaP, GaAs, GaSb, AlN, AlP, AlAs, AlSb, InN, InP, InAs, InSb and mixtures thereof, a ternary compound selected from the groups comprising GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb and mixtures of these, and a quaternary compound selected from a group comprising GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixture of these. On the other hand, the group III-V compound may further comprise a group II metal. For example, InZnP or the like may be selected as a group III-II-V compound.

The group IV-VI compound is a binary compound selected from the group consisting of SnS, SnSe, SnTe, PbS, PbSe, PbTe and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and an quaternary compound selected from the group consisting of SnPbSSe, SnPbSeTe, SnPBSTe, and mixtures thereof.

An example of a group II-IV-V semiconductor compound may be a ternary compound selected from the group consisting of ZnSnP, ZnSnP₂, ZnSnAs₂, ZnGeP₂, ZnGeAs₂, CdSnP₂, and CdGeP₂ and mixtures thereof.

The group IV elements may be selected from the group consisting of Si, Ge and mixtures thereof. The group IV compound may be a binary compound selected from the group consisting of SiC, SiGe, and mixtures thereof.

Each element included in a multi-element compound, such as a binary compound, a ternary compound, and a quaternary compound, may be present in a particle at a uniform concentration or a non-uniform concentration. That is, an expression of a chemical formula indicating the quantum dots means a kind of the element included in the quantum dot compound, and an element ratio in the compound may be different. For example, AgInGaS₂ may mean AgInxGa₁₋ₓS₂ (x is a real number between 0 and 1).

In this case, two-element compound, ternary compound or quaternary compound may be present in a uniform concentration in the particle, or may be present in the same particle with a concentration distribution partially divided into different states. One quantum dot may also have a core/shell structure surrounding the other quantum dot. In the core/shell structure, a concentration of elements present in the shell may have a gradient that decreases toward the core.

In some aspects, the quantum dots may have a core-shell structure comprising a core comprising nanocrystals described above and a shell surrounding the core. The shell of the quantum dots may serve as a protective layer for preventing chemical denaturation of the core to maintain semiconductor properties and/or as a charging layer for imparting electrophoretic properties to the quantum dot. The shell may be a single layer or multiple layers. Examples of the shell of the quantum dot include a metal or non-metal oxide, a semiconductor compound, or a combination thereof.

For example, an oxide of a metal or a non-metal may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O4, but the present disclosure is not limited thereto.

Examples of the semiconductor compound include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb.

The quantum dots may have a full width of half maximum (FWHM) of an emission wavelength spectrum of about 45nm or less, preferably about 40nm or less, more preferably about 30nm or less, and color purity or color reproducibility may be improved in this range. In addition, light emitted through such a quantum dot is emitted in all directions, so that light viewing angle can be improved.

The form of the quantum dot is not particularly limited to a form generally used in the art, but more specifically, a form of spherical, pyramidal, multi-arm, or cubic nanoparticles, nanotubes, nanowires, nanofibers, nanoplate-like particles, or the like can be used.

The quantum dots may adjust an energy band gap by adjusting a size of the quantum dots or adjusting the element ratio in the quantum dot compound, so that light of various wavelength bands may be obtained in a quantum dot light-emitting layer. Therefore, by using the quantum dots (using quantum dots of different sizes or different element ratios in the quantum dot compound) as described above, a light-emitting element that emits light of various wavelengths may be realized. Specifically, an adjustment of the size of the quantum dots or the element ratio in the quantum dot compound may be selected such that red, green and/or blue light is emitted. Further, the quantum dots may be configured such that light of various colors is combined to emit white light.

The smaller the particle size of the quantum dot, the more light in the short wavelength region may be emitted. For example, the particle size of the quantum dot emitting green light in the quantum dot may be smaller than the particle size of the quantum dot emitting red light having the same core. In addition, the particle size of the quantum dot emitting blue light in the quantum dot may be smaller than the particle size of the quantum dot emitting green light having the same core. However, an aspect is not limited thereto, and even in the quantum dot having the same core, the particle size can be adjusted according to a formation material of the shell, a shell thickness, and the like.

The light control patterns CCL1 and CCL2 may include a first light control pattern CCL1 overlapping the second light-emitting area PXA-R and a second light control pattern CCL2 overlapping the third light-emitting area PXA-G. The first light control pattern CCL1 and the second light control pattern CCL2 may be spaced apart from each other. The first light control pattern CCL1 may include a first quantum dot QD1 that converts light of the first wavelength into light of the second wavelength. The second light control pattern CCL2 may include a second quantum dot QD2 that converts light of the first wavelength into light of the third wavelength. In an aspect, the first light control pattern CCL1 may provide a red light, which is light having the second wavelength, and the second light control pattern CCL2 may provide a green light, which is light having the third wavelength. For example, the first quantum dot QD1 may be a red quantum dot, and the second quantum dot QD2 may be a green quantum dot. The same content as that described above may be applied to the quantum dots QD1 and QD2.

Unlike shown in FIG. 8, in another aspect, the light control pattern may include a scattering pattern (not shown) overlapping the first light-emitting area PXA-B. A first opening OP1 overlapping the first light-emitting area PXA-B is defined in the first partition wall BK1, and the scattering pattern may be disposed in the first opening OP1, which overlaps the first light-emitting area PXA- B. The scattering pattern may be provided by transmitting a blue light, which is light of the first wavelength provided by the light-emitting element ELS. The scattering pattern may comprise TiO₂.

Each of the first light control pattern CCL1 and the second light control pattern CCL2 may further include a scattering body (not shown). The first light control pattern CCL1 may include the first quantum dots QD1 and the scattering body, and the second light control pattern CCL2 may include the second quantum dots QD2 and the scattering body.

The scattering body may be an inorganic particle. For example, the scattering body may include at least one of TiO₂, ZnO, Al₂O₃, SiO₂, or hollow silica. The scattering body may include any one of TiO₂, ZnO, Al₂O₃, SiO₂, and hollow silica, or may be a mixture of two or more materials selected from TiO₂, ZnO, Al₂O₃ and SiO₂.

Each of the first light control pattern CCL1 and the second light control pattern CCL2 may include the quantum dots QD1 and QD2 and base resins BR1 and BR2 for dispersing the scattering body. In an aspect, the first light control pattern CCL1 may include the first quantum dots QD1 dispersed in the first base resin BR1, and the second light control pattern CCL2 may include the second quantum dots QD2 dispersed in the second base resin BR2. The base resins BR1 and BR2 may be composed of various resin compositions, which may be generally referred to as binders, as a medium in which the quantum dots QD1 and QD2 and the scattering body are dispersed. For example, the base resins BR1 and BR2 may be an acrylic resin, a urethane resin, a silicone resin, an epoxy resin, or the like. The base resins BR1 and BR2 may be transparent resins. In an aspect, each of the first base resin BR1 and the second base resin BR2 may be the same as or different from each other.

The first light control pattern CCL1 may be formed by ejecting a liquid ink comprising the first quantum dot QD1 to the first opening OP1 by an inkjet method, and the second light control pattern CCL2 may be formed by ejecting a liquid ink comprising the second quantum dot QD2 to the first opening OP1 by an inkjet method.

Referring to FIGS. 8 and 9, the second layer PT2 may be disposed on the first layer PT1. The second layer PT2 may be disposed directly on the first layer PT1. The second layer PT2 may include a second partition wall BK2 and the light-emitting element ELS.

The second partition wall BK2 may be disposed on the first layer PT1. The second partition wall BK2 may include a polymer resin. The second partition wall BK2 may include a polyacrylate-based resin or a polyimide-based resin. The second partition wall BK2 may further include an inorganic material in addition to the polymer resin. An aspect is not limited thereto, the second partition wall BK2 may be formed of an inorganic material. For example, the second partition wall BK2 may include silicon nitride (SiNₓ), silicon oxide (SiOₓ), silicon oxide nitrate (SiOₓN_{y}), or the like. The second partition wall BK2 may be formed of a light absorbing material or may include a black coloring agent. The black coloring agent may comprise a black dye, a black pigment. The black coloring agent may comprise a carbon black, a metal such as chromium, or an oxide thereof. Accordingly, the second partition wall BK2 may prevent color mixing between the first to third light-emitting areas PXA-B, PXA-R, and PXA-G.

A second opening OP2 corresponding to the first opening OP1 may be defined in the second partition wall BK2. The second openings OP2 may overlap the first light-emitting area PXA-B, the second light-emitting area PXA-R, and the third light-emitting area PXA-G, respectively.

The light-emitting element ELS may be disposed in the second opening OP2. The light-emitting element ELS may have a structure of a light-emitting element ELS of an aspect according to FIG. 9, which will be described later. The light-emitting element ELS emits light of the first wavelength.

The light-emitting element ELS may be provided by being patterned by an inkjet printing method. The light-emitting element ELS may include a first light-emitting pattern overlapping the first light-emitting area PXA-B, a second light-emitting pattern overlapping the second light-emitting area PXA-R, and a third light-emitting pattern overlapping the third light-emitting area PXA-G. Each of the second light-emitting pattern overlapping the second light-emitting area PXA-R and the third light-emitting pattern overlapping the third light-emitting area PXA-G may correspond to the first light control pattern CCL1 and the second light control pattern CCL2. The first light-emitting pattern overlapping the first light-emitting area PXA-B, the second light-emitting pattern overlapping the second light-emitting region PXA -R, and the third light-emitting pattern overlapping the third light-emitting region PXA-G may emit light in the same wavelength range, or at least one of them may emit light in a different wavelength range. The first to third light-emitting patterns may all emit light of the first wavelength.

Although FIG. 8 illustrates that all of the light-emitting elements ELS are disposed in the second opening OP2, in another aspect, a portion of first electrodes EL1 (see FIG. 9) in the light-emitting element ELS may overlap the non-light-emitting area NPXA without being disposed in the second open portion OP2. In addition, a second electrode EL2 (see FIG. 9) in the light-emitting element ELS may be a common electrode disposed to completely overlap the light-emitting areas PXA-B, PXA-R, and PXA-G and the non-light-emitting area NPXA.

Although not shown in FIG. 8, the display panel DP may include an insulating layer (not shown) disposed between the reflective member RL and the light-emitting element ELS. Accordingly, the reflective member RL and the first electrode EL1 (see FIG. 9) may be electrically insulated from each other.

The light-emitting element ELS of an aspect may include a first electrode EL1, a hole transport region HTR, a light-emitting layer, an electron transport region ETR, a second electrode EL2, and an encapsulation layer TFE that are sequentially stacked.

The first electrode EL1 may be a transmissive electrode. The first electrode EL1 may include a transparent metal oxide, for example, indium tin oxide (ITO), indium zinc oxide (IZO), zinc oxide (ZnO), indium tin zinc oxide (ITZO), or the like. A light transmittance of the first electrodes EL1 may be 90% or more. The first electrode EL1 may be a cathode or an anode. For example, when the first electrode EL1 is an anode, the second electrode EL2 may be a cathode, and when the first electrode E1 is a cathode, the second electrode E1 may be an anode.

The light-emitting layer may include a plurality of light-emitting stacks ST1, ST2, ST3, and ST4. The plurality of light-emitting stacks ST1, ST2, ST3, and ST4 may include a first light-emitting stack ST1, a second light-emitting stack ST2, a third light-emitting stack ST3, and a fourth light-emitting stack ST4. Although FIG. 9 shows, for example, that the light-emitting element ELS includes a total of four stacks ST1, ST2, ST3, and ST4, the present disclosure is not limited thereto, and the light-emitting device ED may include two, three, or five or more stacks. For example, in the light-emitting element ELS structure illustrated in FIG. 9, the second light-emitting stack ST2 and the third light-emitting stack ST3 may be omitted, and a light-emitting element structure having two stacks, the first light-emitting stack ST1 and the fourth light-emitting stack ST4, may be provided. However, the present disclosure is not limited thereto, and the light-emitting layer may be provided as a single layer.

The light-emitting element ELS according to an aspect may include charge generation layers CGL1, CGL2, and CGL3 disposed between the plurality of light-emitting stacks ST1, ST2, ST3, and ST4. When a voltage is applied, the charge generation layers CGL1, CGL2, and CGL3 may generate charges (electrons and holes) by forming a complex through an oxidation-reduction reaction. The charge generation layers CGL1, CGL2, and CGL3 may provide generated charges to adjacent stacks ST1, ST2, ST3, and ST4, respectively. The charge generation layers CGL1, CGL2, and CGL3 may double an efficiency of current generated in respective adjacent stacks and may serve to adjust the balance of charges between adjacent stacks.

In the light-emitting element ELS according to an aspect, each of the first light-emitting stack ST1, the second light-emitting stack ST2, and the third light- emitting stack ST3 may include blue light-emitting layers BEML1, BEML2, and BEML3 that emit light of the first wavelength. For example, the blue light-emitting layers BEML1, BEML2, and BEML3 may include an organic material that emits light having a wavelength of 420nm or more and 480nm or less. The fourth light-emitting stack ST4 may include a green light-emitting layer GEML4 that emits light of the second wavelength. For example, the green light-emitting layer GEML4 may include an organic material that emits light having a wavelength of 520nm or more and 600nm or less. In this specification, the numerals 1, 2, 3, and 4 after the reference numerals of the blue light-emitting layer BEML and the green light-emitting layer GEML indicate which stack each light-emitting layer is included in.

The first light-emitting stack ST1 may further include the hole transport region HTR that transports holes provided from the first electrode EL1 to the blue light-emitting layer BEML1, and a first intermediate electron transport region that transports electrons generated from the first charge generation layer CGL1 to the blue light-emitting layer BEML1. The hole transport region HTR may include a hole injection layer HIL disposed on the first electrode EL1 and a hole transport layer HTL disposed on the hole injection layer HIL. The hole transport layer HTL may be in contact with the lower surface of the blue light-emitting layer BEML1. The first intermediate electron transport region may include a first intermediate electron transport layer METL1 disposed on the first blue light-emitting layer BEML1.

The second light-emitting stack ST2 may further include a first intermediate hole transport region that transports holes generated from the first charge generation layer CGL1 to the second blue light-emitting layer BEML2, and a second intermediate electron transport region that transports electrons provided from the second charge generation layer CGL2 to the second blue light-emitting layer BEML2. The first intermediate hole transport region may include a first intermediate hole transport layer MHTL1 on the first charge generation layer CGL1. The second intermediate electron transport region may include a second intermediate electron transport layer METL2 disposed on the second blue light-emitting layer BEML2.

The third light-emitting stack ST3 may further include a second intermediate hole transport region that transports holes generated from the second charge generation layer CGL2 to the third blue light-emitting layer BEML3, and a third intermediate electron transport region that transports electrons provided from the third charge generation layer CGL3 to the third blue light-emitting layer BEML3. The second intermediate hole transport region may include a second intermediate hole transport layer MHTL2 disposed on the second charge generation layer CGL2. The third intermediate electron transport region may include a third intermediate electron transport layer METL3 disposed on the third blue light-emitting layer BEML3.

The fourth light-emitting stack ST4 may further include a third intermediate hole transport region that transports holes generated from the third charge generation layer CGL3 to the green light-emitting layer GEML4, and the electron transport region ETR that transports electrons provided from the second electrode EL2 to the green light-emitting layer GEML4. The third intermediate hole transport region may include a third intermediate hole transport layer MHTL3 disposed on the third charge generation layer CGL3. The electron transport region ETR may include an electron transport layer ETL disposed on the green light-emitting layer GEML4 and an electron injection layer EIL disposed on the electron transport layer ETR.

The second electrode EL2 may be a semi-transmissive electrode or a reflective electrode. The second electrode EL2 may include Ag, Mg, Cu, Al, Pt, Pd, Au, Ni, Nd, Ir, Cr, Li, Ca, LiF/Ca (stacked structure of LiF and Ca), LiF/Al (stacked structures of LiF and Al), Mo, Ti, Yb, W, or a compound or a mixture thereof (e.g., AgMg, AgYb, or MgYb). The second electrode EL2 may include a metal material described above, a combination of two or more metal materials selected from the metal materials described above, or an oxide of the metal materials described hereinabove.

The encapsulation layer TFE may cover the second electrode EL2. The encapsulation layer TFE may be a thin film encapsulation layer. The encapsulation layer TFE may be one layer or a plurality of layers stacked. The encapsulation layer TFE includes at least one insulating layer. The encapsulation layer TFE according to an aspect may include at least one inorganic film (hereinafter, an encapsulation inorganic film). In addition, the encapsulation layer TFE according to an aspect may include at least one organic film (hereinafter, an encapsulation organic film) and at least one encapsulation inorganic film.

The encapsulation inorganic film protects the light-emitting layer from moisture/oxygen, and the encapsulation organic film protects a luminescent layer from foreign substances such as dust particles. The encapsulation inorganic film may include, but is not particularly limited to, silicon nitride, silicon oxynitride, silicon oxide, titanium oxide, aluminum oxide, or the like. The encapsulation organic film may comprise an acrylic compound, an epoxy compound, or the like. The encapsulation organic film may comprise a photopolymerizable organic material and is not particularly limited. Unlike shown, the encapsulation layer TFE may be disposed on the second electrode EL2 and may be disposed after filling the second opening OP2.

Referring again to FIG. 8, the third layer PT3 may be disposed on the second layer PT2. The third layer PT3 may correspond to a layer that reflects or transmits light provided in the first layer PT1 and the second layer PT2 or light provided in the display surface DD-IS (see FIG. 3) according to a light wavelength. The third layer PT3 may include a first color filter CF1 and an optical pattern SPC.

The first color filter CF1 may be disposed on the second layer PT2. The first color filter CF1 may transmit light having the first wavelength. For example, the first color filter CF1 may be a blue filter. The first color filter CF1 may include a polymer photosensitive resin and a pigment or dye. The first color filter CF1 may include a blue pigment or a dye. An aspect is not limited thereto, and the first color filter CF1 may not include a pigment or a dye. The first color filter CF1 may include a polymer photosensitive resin and may not include a pigment or a dye. The first color filter CF1 may be transparent. The first color filter CF1 may be formed of a transparent photosensitive resin.

A third opening OP3 overlapping the second light-emitting area PXA-R and the third light-emitting area PXA-G, respectively, may be defined in the first color filter CF1. The third opening OP3 may correspond to the first opening OP1. The third opening OP3 may not be defined in the first light-emitting area PXA-B. An opening is not defined in the first light-emitting area PXA-B, and the first color filter CF1 may be disposed.

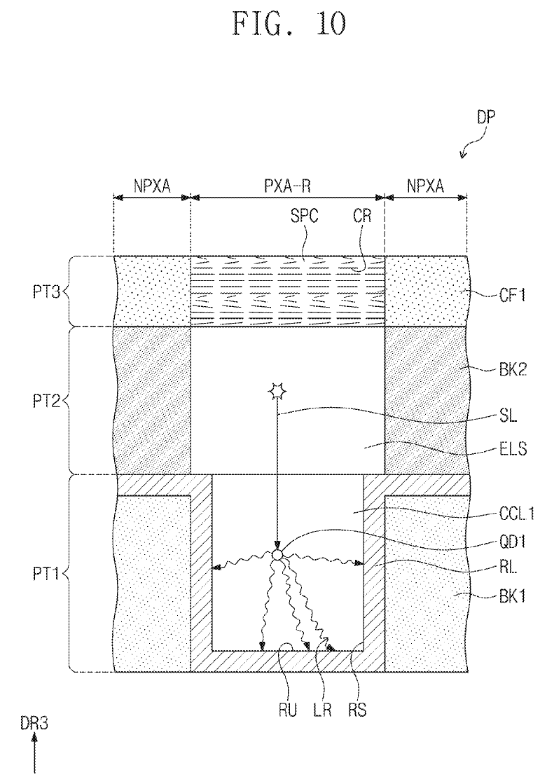

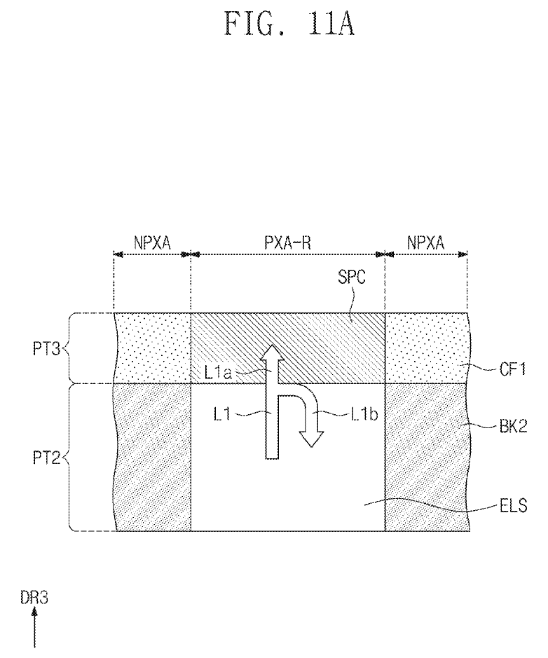

The optical pattern SPC may be disposed in the third opening OP3. The optical pattern SPC may overlap the second light-emitting area PXA-R and the third light-emitting area PXA-G, and may not overlap the first light-emitting area PXA-B. A thickness of the optical pattern SPC may be 1μm or more and 10μm or less. For example, the thickness of the optical pattern SPC may be 1μm or more and 6μm or less. The optical pattern SPC may reflect or transmit light provided in the first layer PT1 and the second layer PT2 or light provided in the display surface DD-IS (see FIG. 3) according to a light wavelength. Elements and functions of the optical pattern SPC will be described below with reference to FIGS. 10 - 11B.

The fourth layer PT4 may be disposed on the third layer PT3. The fourth layer PT4 may include a third partition wall BK3, color filters CF2 and CF3, and an optical layer OL.

The third partition wall BK3 may be disposed on the third layer PT3. The third partition wall BK3 may be disposed to correspond to the non-light-emitting area NPXA. The third partition wall BK3 may divide a boundary between adjacent light-emitting areas PXA-B, PXA-R, and PXA-G. The third partition wall BK3 may be a black matrix. The third partition wall BK3 may be formed of an organic light shielding material or an inorganic light shielding material including a black pigment or a black dye.

A fourth opening OP4 corresponding to the first opening OP1 may be defined in the third partition wall BK3. The fourth openings OP4 may overlap the first light-emitting area PXA-B, the second light-emitting area PXA-R, and the third light-emitting area PXA-G, respectively. Unlike shown, in another aspect, the fourth opening OP4 may have a larger planar area than any one of the first to third openings OP1, OP2, and OP3.

The fourth layer PT4 may include a second color filter CF2 corresponding to the second light-emitting area PXA-R and a third color filter CF3 corresponding to the third light-emitting area PXA-G. The second color filter CF2 may be disposed in the fourth opening OP4 overlapping the second light-emitting area PXA-R, and the third color filter CF3 may be disposed in a fourth opening OP4 overlapping the third light-emitting area PXA-G. Although not shown, the fourth layer PT4 may further include the first color filter disposed in the fourth opening OP4 overlapping the first light-emitting area PXA-B.

The second color filter CF2 may transmit light of the second wavelength, and the third color filter CF3 may transmit light of the third wavelength. For example, the second color filter CF2 may be a red filter, and the third color filter CF3 may be a green filter. Each of the color filters CF2 and CF3 may include a polymer photosensitive resin and a pigment or dye. The second color filter CF2 may include a red pigment or dye, and the third color filter CF3 may include a green pigment or dye. In addition, in an aspect, each of the color filters CF2 and CF3 may be a filter. The second color filter CF2 and the third color filter CF3 may be provided integrally without being distinguished from each other.

The fourth layer PT4 may include the optical layer OL disposed on the color filters CF1 and CF2. The optical layer OL may control reflected light from the display panel DP by external light. Unlike shown, the optical layer OL in the display panel DP of an aspect may be omitted.

A base substrate (not shown) may be disposed on the optical layer OL. The base substrate (not shown) may be a glass substrate, a metal substrate, a plastic substrate, or the like. However, an aspect is not limited thereto, and the base substrate (not shown) may be an inorganic layer, an organic layer, or a composite material layer. The display panel DP according to an aspect may further include a filling layer (not shown) disposed between the fourth layer PT4 and the base substrate (not shown). The filling layer (not shown) may be an organic layer. The filling layer (not shown) may include at least one of an acrylic resin, a silicone resin, or an epoxy resin. The base substrate (not shown) and the filling layer (not shown) may be omitted.

Unlike shown in FIG. 8, in another aspect, the fourth layer PT4 may not include the third partition wall BK3. For example, the second color filter CF2 or the third color filter CF3 may be disposed in the non-light-emitting area NPXA defined between the second light-emitting area PXA-R and the third light-emitting area PXA-G. The second color filter CF2 may be disposed at a portion adjacent to the second light-emitting area PXA-R in the non-light-emitting area NPXA defined between the second light-emitting region PXA−R and the third light-emitting area PXA−G, and the third color filter CF3 may be disposed at a portion adjacent to the third light-emitting region PXA-G in the non-light-emitting area NPXA defined between the second light-emitting area PXA−R and third light-emitting areas PXA−G. Alternatively, at least one of the plurality of color filters CF1, CF2, and CF3 may be stacked on the non-light-emitting area NPXA. For example, the first to third color filters CF1, CF2, and CF3 may be stacked sequentially in an arbitrary order.

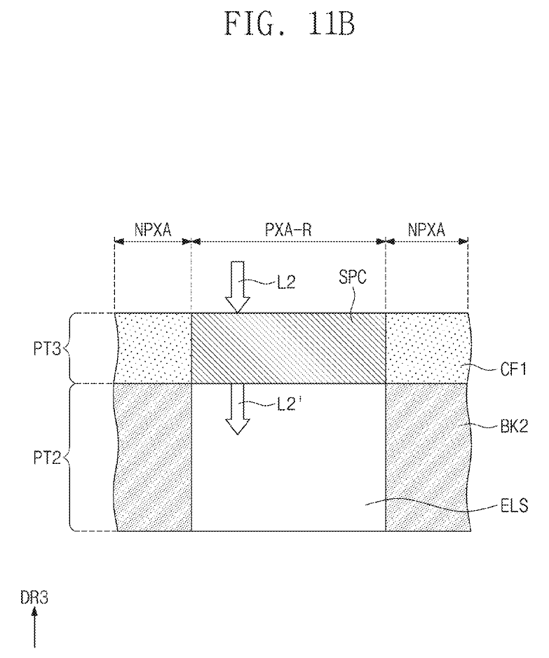

FIG. 10 is an enlarged cross-sectional view of a portion of a display panel according to an aspect of the present disclosure. FIGS. 11A and 11B are enlarged cross-sectional views of a portion of a display panel according to an aspect of the present disclosure. In FIG. 10, only first to third layers PT1, PT2, and PT3 overlapping the second light-emitting area PXA-R are illustrated for convenience of description, and in FIGS. 11A and 11B, only the first and second layers PT1 and PT2 overlapping the second light-emitting area PXA-R are illustrated. In addition, FIG. 10 schematically illustrates a path in which a light SL and LR is emitted, converted, and proceeds in the first layer PT1 and the second layer PT2, FIG. 11A schematically illustrates a path through which a light L1 is transmitted and reflected from the second layer PT2 to the third layer PT3, and FIG. 11B schematically illustrates a path from which the external a light L2 is transmitted and reflected to the second layer PT2 from the third layer PT3. In the following description of the display panel DP according to an aspect of the present disclosure with reference to FIGS. 10, 11A, and 11B the same reference numerals are given to the configurations described in advance with reference to FIGS. 4 - FIG. 9, and detailed description thereof will be omitted.

Referring to FIG. 10, the third layer PT3 includes an optical pattern SPC overlapping the second light-emitting area PXA-R. The optical pattern SPC includes a photonic crystal CR. As the optical pattern SPC includes the photonic crystal CR, it may perform a function of reflecting or transmitting light according to a light wavelength. The photonic crystal CR may reflect blue light. The photonic crystal CR may reflect the light SL of a first wavelength in the second light-emitting area PXA-R and transmit the light LR of a second wavelength. For example, the photonic crystal CR may have a reflectance of 45% or more and 95% or less with respect to the light SL of the first wavelength in the second light-emitting area PXA-R, and may have a transmittance of 90% or more with respect to the light LR of the second wavelength.

The photonic crystal CR may include a helical photonic crystal. Herein, a helical photonic crystal may refer to a photonic crystal comprising a helical structure or comprising a helical molecular arrangement. When the photonic crystal CR includes a right-handed helical photonic crystal, blue light with a right-handed circular polarization may transmit through the optical pattern SPC, and blue light of a left-handed circular polarization may reflected by the optical pattern SPC. When the photonic crystal CR includes a left handed helical photonic crystal, left-handed circularly polarized blue light may be transmitted through the optical pattern SPC, and right-handed circularly polarized blue light may reflected by the optical pattern SPC.

When the photonic crystal CR includes a helical photonic crystal, the helical photonic crystal may be a single stranded helix or a double stranded helix. The helical photonic crystal may include a plurality of complete helix turns. In this case, the number of complete helices turns may be 4 or more and 50 or less. The pitch of the helical photonic crystal, i.e. the height measured parallel to the axis of the helix of one complete helix turn, may be greater than or equal to 200nm and less than or equal to 350 nm. For example, the pitch may be greater than or equal to 250nm and less than or equal to 350nm. A refractive index anisotropy Δn of the helical photonic crystal may be greater than or equal to 0.1 and less than or equal to 0.3. For example, the refractive index anisotropy for light of the first wavelength of the helical photonic crystal may be greater than or equal to 0.15 and less than or equal to 0.25.

The first layer PT1 may include a reflective member RL overlapping the second light-emitting area PXA-R, and a first light control pattern CCL1 overlapping the second light-emitting area PXA -R, disposed on the reflective member RL, and including a first quantum dot QD1. The second layer PT2 may include a light-emitting element ELS overlapping the second light-emitting area PXA-R.

The light-emitting element ELS may generate the light SL having the first wavelength, and at least a part of the generated light SL having the first wavelength may reach the first quantum dot QD1 of the first light control pattern CCL1. The light SL that reaches first wavelength may be converted into the light LR of the second wavelength due to the first quantum dot QD1. The converted light LR of the second wavelength may be reflected at each of a bottom surface RU of the reflective member RL and a side surface RS of the reflective member RL. Accordingly, the light LR having the second wavelength may be directed in a direction toward the third layer PT3, that is, in the third direction DR3.

Referring to FIGS. 10 and 11A, the light L1 supplied from the second layer PT2 to the third layer PT3 may include a light L1a supplied to the third layer PT3, and a light L1b returning to the second layer PT2, respectively. The light L1a supplied to the third layer PT3 may be light that passes through the optical pattern SPC, and the light L1b returning to the second layer PT2 may be light reflected by the optical pattern SPC.

The light L1 supplied from the second layer PT2 to the third layer PT3 may include the light SL of the first wavelength and the light LR of the second wavelength in the second light-emitting area PXA-R. A portion of the light SL of the first wavelength generated by the light-emitting element ELS in the second layer PT2 is converted into the light LR of the second wavelength by the first quantum dot QD1, and the remaining portion of the light SL of the first wavelength may reach the third layer PT3 as blue light.

The light SL having the first wavelength among the light L1 supplied from the second layer PT2 to the third layer PT3 may be reflected by the photonic crystal CR. In the third layer PT3, 45% or more and 95% or less of the light SL of the first wavelength may be returned to the second layer PT2 by the photonic crystal CR. The light LR having the second wavelength among the light L1 supplied from the second layer PT2 to the third layer PT3 may transmit through the photonic crystal CR. With the photonic crystal CR, 90% or more of the light LR of the second wavelength may pass through the third layer PT3.

Referring to FIGS. 10 and 11B, the external light L2 may reach the second layer PT2 through the third layer PT3. The external light L2 may be light provided on the display surface DD-IS (see FIG. 3). The light having the first to third wavelengths included in the external light L2 may be reflected or transmitted by the photonic crystal CR. Among the light having the first to third wavelengths included in the external light L2, the light transmitted through the optical pattern SPC, which includes the photonic crystal CR, may reach the second layer PT2. The light arriving at the second layer PT2 may be included in the light SL of the first wavelength generated by the light-emitting element ELS or the light LR of the second wavelength converted by the first quantum dot QD1. The light emission efficiency of the display panel DP may be improved through the external light L2.

In FIG. 10 to FIG. 11B, descriptions of the second light-emitting area PXA-R, the first light control pattern CCL1, the first quantum dot QD1, and the light LR of the second wavelength are illustrated, but the same descriptions may be applied to the third light-emitting area PXA-G and the second light control pattern CCL2, the second quantum dot QD2, and the light of a third wavelength described above in FIG. 8. For example, the photonic crystal CR may have a reflectance of 45% or more and 95% or less with respect to the light SL of the first wavelength in the third light-emitting area PXA-G, and the photonic crystal CR may have a transmittance of 90% or more with respect to the light of the third wavelength in the third light-emitting area PXA-G.

The display panel according to an aspect of the present disclosure includes a photonic crystal, so that a quantity of blue light emitted to the display surface in a red or green light-emitting area is relatively reduced, so that light emission efficiency may be improved and color purity may be increased. In conventional display devices, when a light-emitting element that generates blue light and quantum dots are disposed under the light-emitting element, some blue light may not be converted into red or green light by the quantum dots and is emitted. However, since the display panel according to an aspect of the present disclosure includes the photonic crystal, it is possible to improve light emission efficiency and increase color purity by reflecting blue light and confining the blue light in the area of the quantum dots. In addition, in conventional display devices, in order to solve the problem of blue light emission, a functional layer such as a reflective member is further disposed on the light-emitting element to improve color purity, but not only is blue light reflected but also red or green light which lowers light emission efficiency. However, by including the photonic crystal according to an aspect of the present disclosure, reflectance according to a light wavelength may be adjusted, which improves the color purity and the light emission efficiency by reflecting substantially only blue light. In addition, the display panel according to an aspect of the present disclosure includes the photonic crystal, so that external light may be utilized for internal light emission to improve light emission efficiency. A display panel according to an aspect of the present disclosure and an electronic device including the same may have improved display efficiency and quality, thereby improving reliability.

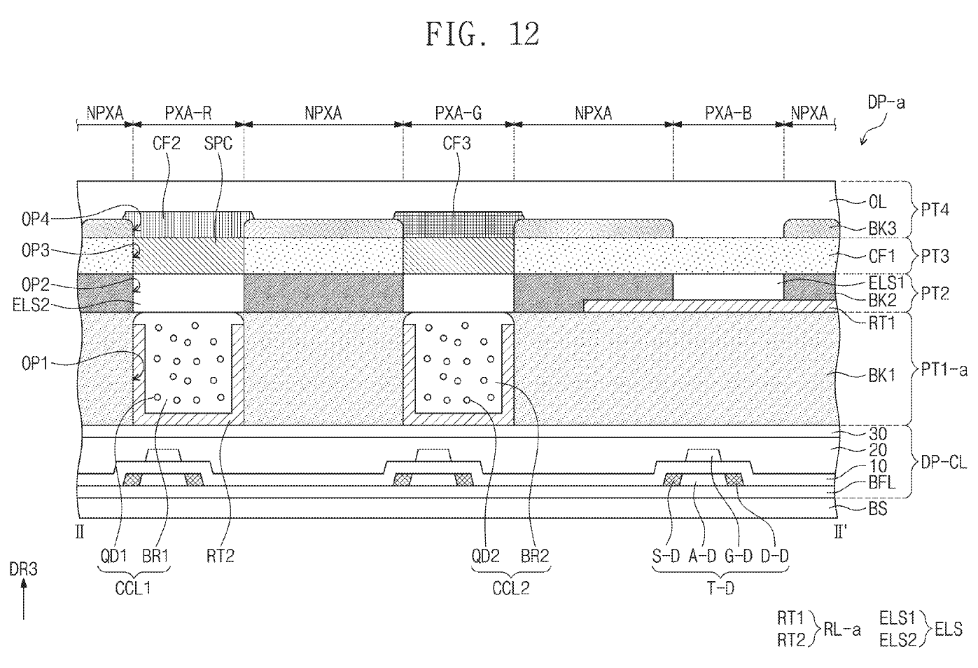

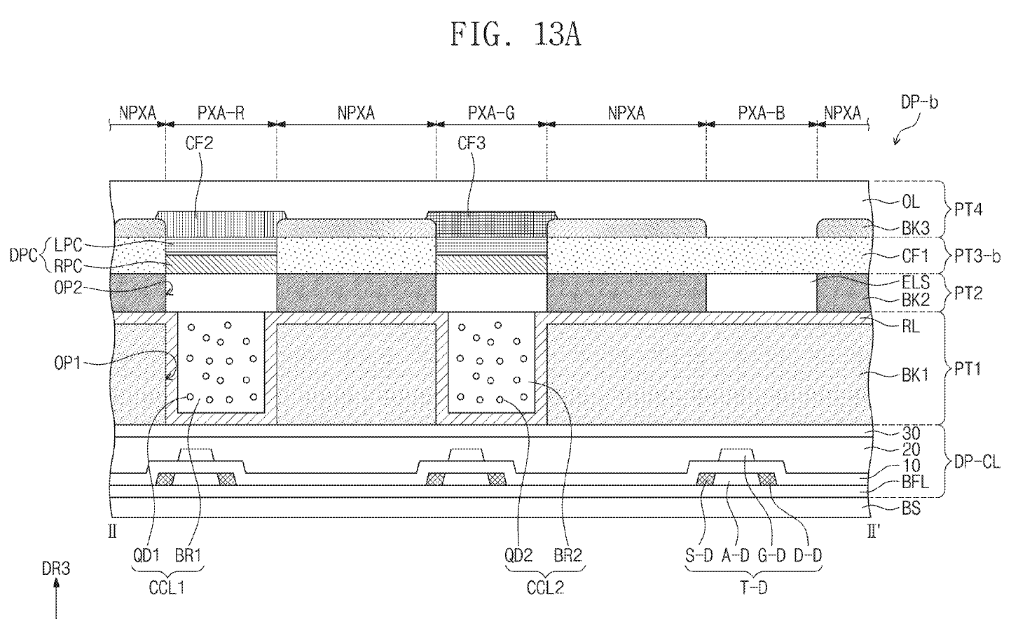

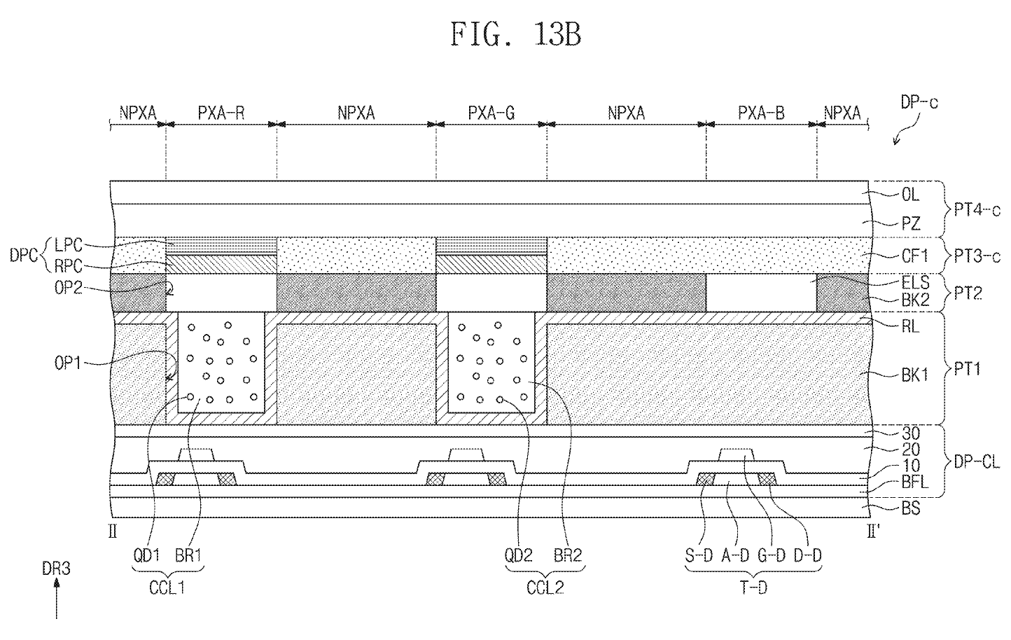

FIG. 12 is a cross-sectional view of a display panel according to another aspect of the present disclosure. FIGS. 13A and 13B are cross-sectional views of a display panel according to another aspect of the present disclosure. FIGS. 12- 13B illustrate display panels DP-a, DP-b, and DP-c of another aspect corresponding to the display panel DP of FIG. 8. Differences from the display panel DP in FIG. 8 will be described below, and the same reference numerals will be given to elements described above, and detailed descriptions thereof will be omitted.

Referring to FIG. 12, the display panel DP-a may include a first layer PT1-a, and may include the second to fourth layers PT2, PT3, and PT4 disposed on the first layer PT1-a.

In the first layer PT1-a, a reflective member RL-a may include a first portion RT1 overlapping the first light-emitting area PXA-B and a second portion RT2 overlapping each of the second light-emitting area PXA-R and the third light-emitting area PXA-G. The reflective member RL-a may be one that is not provided continuously and integrally. The first portion RT1 may be disposed on an upper surface of a first partition wall BK1 overlapping the first light-emitting area PXA-B. A light-emitting element ELS1 may be disposed on an upper surface of the first portion RT1. The second portion RT2 may be disposed in the first opening OP1 overlapping each of the second light-emitting area PXA-R and the third light-emitting area PXA-G. The second portion RT2 may be spaced apart from a light-emitting element ELS2 with the first light control pattern CCL1 and the second light control pattern CCL2 interposed therebetween. Unlike the reflective member RL of FIG. 8 described above, the second portion RT2 may be spaced apart from the second partition wall BK2 in a cross section.

Referring to FIGS. 13A and 13B, the display panels DP-b and DP-c may include sequentially stacked the first layer PT1, the second layer PT2, third layers PT3-b and PT3-c, and fourth layers PT4 and PT4-c.

The third layers PT3-b and PT3-c may include an optical pattern DPC overlapping the second light-emitting area PXA-R and the third light-emitting area PXA-G. The optical pattern DPC may refer to a double optical pattern in which the optical pattern SPC described above with reference to FIG. 8 is composed of a double layer.

The optical pattern DPC may include a first optical pattern RPC including a first photonic crystal and a second optical pattern LPC including a second photonic crystal. A thickness of each of the first optical pattern RPC and the second optical pattern LPC may be greater than or equal to 1μm and less than or equal to 6μm. For example, the thickness of each of the first optical pattern RPC and the second optical pattern LPC may be 1μm or more and 3μm or less, and a thickness of the optical pattern DPC may be 2μm or more and 6μm or less. The above-described description of the photonic crystal CR (see FIG. 8) may be equally applied to each of the first photonic crystal included in the first optical pattern RPC and the second photonic crystal included in the second optical pattern LPC.

Each of the first photonic crystal and the second photonic crystal includes a helical photonic crystal, and handedness of the first photonic crystal and the second photonic crystal may be different. For example, when the first photonic crystal includes a righthanded helical photonic crystal, the second photonic crystal may include a left-handed helical photonic crystal. Among the light L1 (see FIG. 11A) directed from the second layer PT2 to the third layers PT3-b and PT3-c, blue light with right-handed circular polarization may be transmitted through the first optical pattern RPC, and blue light of the left-handed circular polarization may be reflected by the first optical pattern RPC. But blue light with right-handed circular polarization transmitted through the first optical pattern RPC may be reflected by the second optical pattern LPC. Accordingly, the optical pattern DPC including the first optical pattern RPC and the second optical pattern LPC may have a reflectance of 90% or more with respect to blue light. In another aspect, when the first photonic crystal includes a left-handed helical photonic crystal, the second photonic crystal may include a right-handeds helical photonic crystal. In another aspect, among the light L1 (see FIG. 11A) directed from the second layer PT2 to the third layers PT3-b and PT3-c, blue light with left-handed circular polarization may be transmitted through the first optical pattern RPC, and blue light with right-handed circular polarization may be reflected by the first optical pattern RPC. In this case, the blue light with left-handed circular polarization transmitted through the first optical pattern RPC may be reflected by the second optical pattern LPC. Accordingly, the optical pattern DPC including the first optical pattern RPC and the second optical pattern LPC may have a reflectance of 90% or more with respect to blue light.

Referring to FIG. 13B, the fourth layer PT4-c may include a polarizer PZ. The fourth layer PT4-c may not include a color filter as compared with the fourth layer PT4 illustrated in FIG. 8. The polarizer PZ may be disposed to completely overlap the light-emitting areas PXA-B, PXA-R, and PXA-G and the non-light-emitting area NPXA. The polarizer PZ may include a circularly polarizing plate. When the polarizer PZ includes a circularly polarizing plate, only one of a right-handed circularly polarized light and a left-handed circularly polarized light may pass through the polarizer PZ.

Although preferred aspects of the present disclosure have been described above, it will be understood that those skilled in the art or those skilled in the relevant art may make various modifications and changes to the present disclosure without departing from the spirit and technical scope of the present disclosure. Therefore, the present disclosure should not be limited to the contents described in the detailed description of the specification.

What is claimed is:

1. A display panel comprising:
a display area comprising a first light-emitting area emitting a light of a first wavelength and a second light-emitting area adjacent to the first light-emitting area and emitting a light of a second wavelength different from the first wavelength;
a non-light-emitting area surrounding the first and the second light-emitting areas;
a base layer;
a first layer disposed on the base layer and comprising a light control pattern overlapping the second light-emitting area;
a second layer disposed on the first layer and comprising a light-emitting element emitting the light of the first wavelength; and
a third layer disposed on the second layer and comprising an optical pattern overlapping the second light-emitting area,
wherein the optical pattern comprises a photonic crystal.

2. The display panel of claim 1, wherein the third layer comprises a first color filter overlapping the first light-emitting area and the non-light-emitting area, the first color filter transmitting the light of the first wavelength.

3. The display panel of claim 1, further comprising a fourth layer disposed on the third layer, and
wherein the fourth layer comprises a second color filter overlapping the second light-emitting area, the second color filter transmitting the light of the second wavelength.

4. The display panel of claim 1, further comprising a fourth layer disposed on the third layer, and
wherein the fourth layer comprises a polarizer overlapping the first light-emitting area, the second light-emitting area and the non-light-emitting area.

5. The display panel of claim 1, wherein the light of the first wavelength is blue light.

6. The display panel of claim 1, wherein the light control pattern comprises a first quantum dot, and
wherein the first quantum dot converts the light of the first wavelength into the light of the second wavelength.

7. The display panel of claim 1, wherein a thickness of the optical pattern is 1μm or more and 10μm or less.

8. The display panel of claim 1, wherein the optical pattern has a reflectance of 45% or more with respect to the light of the first wavelength.

9. The display panel of claim 1, wherein the optical pattern has a transmittance of 90% or more with respect to the light of the second wavelength.

10. The display panel of claim 1, wherein the photonic crystal comprises a helical photonic crystal.

11. The display panel of claim 10, wherein the optical pattern comprises a first optical pattern comprising the helical photonic crystal, and a second optical pattern disposed on the first optical pattern and comprising a second helical photonic crystal, the second helical photonic crystal has a handedness different from that of the helical photonic crystal.

12. The display panel of claim 11, wherein the optical pattern has a reflectance of 90% or more with respect to the light of the first wavelength.

13. The display panel of claim 10, wherein the helical photonic crystal comprises a plurality of complete helix turns, and
wherein the number of the plurality of complete helix turns is four or more.

14. The display panel of claim 13, wherein a pitch of the helical photonic crystal is greater than or equal to 200 nm and less than or equal to 350 nm.

15. The display panel of claim 10, wherein a refractive index anisotropy of the optical pattern with respect to the light of the first wavelength is 0.1 or more and 0.3 or less.

16. The display panel of claim 1, wherein the first layer further comprises a first partition wall in which a first opening overlapping the second light-emitting area is defined, and a reflective member disposed in the first opening.

17. The display panel of claim 16, wherein the light control pattern is disposed on the reflective member.

18. The display panel of claim 1, wherein the light-emitting element comprises a first light-emitting pattern overlapping the first light-emitting area and a second light-emitting pattern overlapping the second light-emitting area,
wherein the light control pattern is disposed below the second light-emitting pattern, and
wherein the optical pattern is disposed on the second light-emitting pattern.

19. The display panel of claim 1, further comprising a circuit element layer disposed between the base layer and the first layer.

20. An electronic apparatus providing an image, the electronic apparatus comprising: a display device, and a power module supplying power to the display device,
the display device comprises a display panel and a window disposed on the display panel,
the display panel comprises:
a display area comprising a first light-emitting area emitting a light of a first wavelength and a second light-emitting area adjacent to the first light-emitting area and emitting a light of a second wavelength different from the first wavelength,
a non-light-emitting area surrounding the first and the second light-emitting areas;
a base layer;
a first layer disposed on the base layer and comprising a light control pattern overlapping the second light-emitting area;
a second layer disposed on the first layer and comprising a light-emitting element emitting the light of the first wavelength; and
a third layer disposed on the second layer and comprising an optical pattern overlapping the second light-emitting area,
wherein the optical pattern comprises a photonic crystal.
